(19) United States
(12) Patent Application Publication
(10) Pub. No.: US 2025/0142868 A1
(43) Pub. Date: May 1, 2025

(54) GATE TRENCH POWER SEMICONDUCTOR DEVICES HAVING CHANNELS WITH HORIZONTAL AND VERTICAL SEGMENTS

(71) Applicant: Wolfspeed, Inc., Durham, NC (US)

(72) Inventors: Woongsun Kim, Cary, NC (US); Naeem Islam, Morrisville, NC (US); Madankumar Sampath, Morrisville, NC (US); Sei-Hyung Ryu, Cary, NC (US)

(21) Appl. No.: 18/495,085

(22) Filed: Oct. 26, 2023

(51) Int. Cl. H01L 29/78; H01L 29/16; H01L 29/423

(52) U.S. Cl. CPC H10D 30/615; H10D 30/668; H10D 62/8325; H10D 64/513

(57) ABSTRACT

Semiconductor devices are provided that comprise a semiconductor layer structure that comprises a drift region having a first conductivity type, a channel region having a second conductivity type, and a source region having the first conductivity type. A gate trench extends into an upper surface of the semiconductor layer structure. The channel region horizontally overlaps both the gate trench and the source region.

### FIELD OF THE INVENTION

The present invention relates to power semiconductor devices and, more particularly, to power semiconductor devices having gate trenches and to methods of fabricating such devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region are formed in the semiconductor layer structure that are separated by a channel region. A gate electrode (which may act as the gate terminal or be electrically connected to the gate terminal) is disposed adjacent the channel region and separated from the channel region by a thin oxide layer. A MOSFET may be turned on or off by setting a bias voltage that is applied to the gate electrode to be above or below a threshold value. When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

As noted above, the gate electrode of a MOSFET is separated from the channel region by a thin oxide layer that is called a gate oxide layer. Other non-oxide gate dielectric layers may be used in certain applications in place of the gate oxide layer. It will be appreciated that the techniques according to embodiments of the present invention that are described herein are equally applicable to devices having gate dielectric layers formed with materials other than oxides.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit (since the drive circuit only charges and discharges the gate electrode of the MOSFET).

In some applications, MOSFETs may need to carry large currents and/or be capable of blocking high voltages. Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the top surface of the semiconductor layer structure and the drain may be on the bottom surface of the semiconductor layer structure). The semiconductor layer structure may or may not include an underlying substrate such as a growth substrate.

The semiconductor layer structure of a power semiconductor device typically includes an “active region” in which one or more functional semiconductor devices are formed. The active region acts as a main junction for blocking voltage during reverse bias (off-state) operation and providing current flow during forward bias (on-state) operation. The power semiconductor device may also have an edge termination structure such as guard rings or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Vertical power semiconductor devices that include a MOSFET can have a planar gate electrode design in which the gate electrode of the transistor is formed on top of the semiconductor layer structure or, alternatively, may have the gate electrode buried in a gate trench within the semiconductor layer structure. MOSFETs having buried gate electrodes are typically referred to as gate trench MOSFETs. With the planar gate electrode design, the channel region of each unit cell transistor is horizontally disposed underneath the gate electrode. In contrast, in the gate trench MOSFET design, the channels are typically vertically disposed adjacent sidewalls of the gate electrodes. Gate trench MOSFETs may provide enhanced performance, but typically require a more complicated manufacturing process.

### SUMMARY

Pursuant to some embodiments of the present invention, semiconductor devices are provided that comprise a silicon carbide based semiconductor layer structure and a gate trench extending into an upper surface of the semiconductor layer structure. The semiconductor layer structure comprises a drift region having a first conductivity type, a channel region having a second conductivity type, and a source region having the first conductivity type. The channel region horizontally overlaps the source region.

In some embodiments, the channel region may extend to the upper surface of the semiconductor layer structure.

In some embodiments, the semiconductor layer structure may further comprise a deep well region having the second conductivity type underneath the source region, the deep well region having a maximum doping concentration that exceeds a maximum doping concentration of a channel portion of the channel region. In some embodiments, the maximum doping concentration of the deep well region may exceed the maximum doping concentration of the channel portion of the channel region by at least an order of magnitude. In some embodiments, a lower surface of the deep well region may be farther from the upper surface of the semiconductor layer structure than is a lower surface of the channel region. In some embodiments, the channel region may horizontally overlap the deep well region. In some embodiments, a sidewall of the source region may be substantially aligned with a sidewall of the deep well region. In some embodiments, a sidewall of the source region may extend closer to the gate trench than a sidewall of the deep well region. In some embodiments, a sidewall of the deep well region may extend closer to the gate trench than a sidewall of the source region.

In some embodiments, the semiconductor layer structure may further comprise a JFET region having the first conductivity type on the drift region, the JFET region having a doping concentration that is higher than a doping concentration of the drift region, wherein the deep well region extends into the JFET region. In some embodiments, the gate trench may be a first gate trench and a second gate trench may extend into the upper surface of the semiconductor layer structure, where the semiconductor layer structure further comprises a support shield having the second conductivity type that is positioned in between the first and second gate trenches. In some embodiments, the support shield may extend through the JFET region into the drift region.

In some embodiments, the semiconductor device may further comprise a gate electrode having a first portion that is within the gate trench and a second portion that is on the upper surface of the semiconductor layer structure, and the second portion of the gate electrode may vertically overlap the channel region and the source region. In some embodiments, the semiconductor device may further comprise a gate dielectric layer that has a horizontal segment that extends on an upper surface of the channel region and that directly contacts both the second portion of the gate electrode and the channel region.

In some embodiments, the drift region, the channel region and the source region may comprise silicon carbide.

In some embodiments, the channel region may be configured so that during on-state operation current flows parallel to the upper surface of the semiconductor layer structure in a first portion of the channel region and flows perpendicular to the upper surface of the semiconductor layer structure in a second portion of the channel region.

In some embodiments, the channel region may also horizontally overlap the gate trench.

Pursuant to further embodiments of the present invention, semiconductor devices are provided that comprise a silicon carbide based semiconductor layer structure and a gate trench extending into an upper surface of the semiconductor layer structure. The semiconductor layer structure comprises a drift region having a first conductivity type, a channel region having a second conductivity type, and a source region having the first conductivity type. The channel region extends to the upper surface of the semiconductor layer structure.

In some embodiments, the semiconductor device may further comprise a gate electrode having a first portion that is within the gate trench and a second portion that is on an upper surface of the semiconductor layer structure. In some embodiments, the second portion of the gate electrode may vertically overlap the channel region and the source region.

In some embodiments, the semiconductor device may further comprise a gate dielectric layer in between the gate electrode and the semiconductor layer structure, where an upper surface of the channel region directly contacts the gate dielectric layer. In some embodiments, the gate dielectric layer may have a horizontal segment that extends on an upper surface of the channel region and that directly contacts the second portion of the gate electrode.

In some embodiments, the semiconductor layer structure may further comprise a deep well region having the second conductivity type underneath the source region, the deep well region having a maximum doping concentration that exceeds a maximum doping concentration of a channel portion of the channel region. In some embodiments, the maximum doping concentration of the deep well region may exceed the maximum doping concentration of the channel portion of the channel region by at least an order of magnitude. In some embodiments, a lower surface of the deep well region may be farther from the upper surface of the semiconductor layer structure than is a lower surface of the channel region. In some embodiments, the channel region may horizontally overlap the deep well region. In some embodiments, the semiconductor layer structure may further comprise a JFET region having the first conductivity type on the drift region, the JFET region having a doping concentration that is higher than a doping concentration of the drift region, wherein the deep well region extends into the JFET region.

In some embodiments, the drift region, the channel region and the source region may comprise silicon carbide.

In some embodiments, the channel region may be configured so that during on-state operation current flows parallel to the upper surface of the semiconductor layer structure in a first portion of the channel region and flows perpendicular to the upper surface of the semiconductor layer structure in a second portion of the channel region.

In some embodiments, a first portion of the channel region that is in between the source region and the gate trench may be wider than a second portion of the channel region that is below the first portion of the channel region. In other embodiments, a first portion of the channel region that is in between the source region and the gate trench may be narrower than a second portion of the channel region that is below the first portion of the channel region.

Pursuant to additional embodiments of the present invention, semiconductor devices are provided that comprise a silicon carbide based semiconductor layer structure, a gate trench extending into an upper surface of the semiconductor layer structure, and a second gate trench adjacent the first gate trench and extending into the semiconductor layer structure. The semiconductor layer structure comprises a drift region having a first conductivity type, a channel region having a second conductivity type, a deep well region having the second conductivity type, a support shield having the second conductivity type, and a source region having the first conductivity type. The deep well region has a higher second conductivity type dopant concentration than the channel region, and the support shield is in between the first and second gate trenches and extends deeper into the semiconductor layer structure than the deep well region

In some embodiments, the channel region may be below the source region and horizontally overlaps the deep well region.

In some embodiments, the channel region may extend to the upper surface of the semiconductor layer structure.

In some embodiments, the second conductivity type dopant concentration of the deep well region may exceed the second conductivity type dopant concentration of the channel region by at least an order of magnitude.

In some embodiments, a lower surface of the deep well region may be farther from an upper surface of the semiconductor layer structure than is a lower surface of the channel region.

In some embodiments, the source region may include a first region having a first dopant concentration and a second region having a second dopant concentration that is less than the first dopant concentration, where the second region is in between the first gate trench and the second region.

In some embodiments, the semiconductor layer structure may further comprise a JFET region having the first conductivity type on the drift region, the JFET region having a doping concentration that is higher than a doping concentration of the drift region, where the deep well region extends into the JFET region. In some embodiments, the support shield may extend through the JFET region into the drift region.

In some embodiments, the drift region, the channel region and the source region may comprise silicon carbide.

Pursuant to other embodiments of the present invention, methods of fabricating a semiconductor device are provided. Pursuant to these methods, a silicon carbide based semiconductor layer structure is provided that comprises a first conductivity type drift region and a second conductivity type layer on top of the drift region, the second conductivity type layer extending to an upper surface of the semiconductor layer structure. First conductivity type dopants are selectively implanted into the upper surface of the second conductivity type layer to form a plurality of spaced apart source regions in the upper surface of the semiconductor layer structure. A plurality of gate trenches are formed in the upper surface of the semiconductor layer structure, the gate trenches dividing the second conductivity type layer into a plurality of second conductivity type well regions. A gate dielectric layer is formed in the gate trench and on the upper surface of the semiconductor layer structure, the gate dielectric layer directly contacting both a side surface and an upper surface of a first of the second conductivity type well regions.

In some embodiments, each second conductivity type well region may comprise a channel region that is adjacent a respective one of the gate trenches, a deep well region that is underneath a respective one of the source regions and a well contact region that is laterally adjacent the respective one of the source regions. In some embodiments, a second conductivity type dopant concentration of a first of the deep well regions exceeds a second conductivity type dopant concentration of a first of the channel regions by at least an order of magnitude. In some embodiments, a first of the channel regions horizontally overlaps both a first of the gate trenches and a first of the source regions. In some embodiments, a first of the channel regions extends to an upper surface of the semiconductor layer structure.

Pursuant to still further embodiments of the present invention, semiconductor devices are provided that comprise a semiconductor layer structure and a gate trench extending into an upper surface of the semiconductor layer structure. The semiconductor layer structure comprises a drift region having a first conductivity type, a channel region having a second conductivity type, and a source region having the first conductivity type. The channel region has a horizontal segment and a vertical segment, and the vertical segment extends deeper into the semiconductor layer structure than the horizontal segment.

In some embodiments, the channel region extends to the upper surface of the semiconductor layer structure.

In some embodiments, the channel region horizontally overlaps the source region.

In some embodiments, the semiconductor layer structure further comprises a deep well region having the second conductivity type underneath the source region, the deep well region having a maximum doping concentration that exceeds a maximum doping concentration of a channel portion of the channel region.

In some embodiments, a lower surface of the deep well region is farther from the upper surface of the semiconductor layer structure than is a lower surface of the channel region.

In some embodiments, a sidewall of the source region is substantially aligned with a sidewall of the deep well region.

In some embodiments, a sidewall of the source region extends closer to the gate trench than a sidewall of the deep well region.

In some embodiments, a sidewall of the deep well region extends closer to the gate trench than a sidewall of the source region.

In some embodiments, the semiconductor device further comprises a gate electrode having a first portion that is within the gate trench and a second portion that is on the upper surface of the semiconductor layer structure, wherein the second portion of the gate electrode vertically overlaps the channel region and the source region.

Pursuant to still yet additional embodiments of the present invention, semiconductor devices are provided that comprise a semiconductor layer structure and a gate trench extending into an upper surface of the semiconductor layer structure. The semiconductor layer structure comprises a drift region having a first conductivity type, a channel region having a second conductivity type, a deep well region having the second conductivity type, and a source region having the first conductivity type. The source region vertically overlaps the deep well region and a sidewall of the deep well region that faces the gate trench is not aligned along a vertical axis with a sidewall of the source region that faces the gate trench, and the deep well region has a higher second conductivity type dopant concentration than the channel region.

In some embodiments, the channel region may extend to the upper surface of the semiconductor layer structure.

In some embodiments, the second conductivity type dopant concentration of the deep well region may exceed the second conductivity type dopant concentration of the channel portion of the channel region by at least an order of magnitude.

In some embodiments, a lower surface of the deep well region may be farther from the upper surface of the semiconductor layer structure than is a lower surface of the channel region.

In some embodiments, the channel region may horizontally overlap the source region.

In some embodiments, the semiconductor device may further comprise a gate electrode having a first portion that is within the gate trench and a second portion that is on the upper surface of the semiconductor layer structure, where the second portion of the gate electrode vertically overlaps the channel region and the source region.

### BRIEF DESCRIPTION OF THE DRAWINGS

FIG. 1 is a schematic cross-sectional view of a unit cell of a gate trench power MOSFET.

FIG. 2A is a schematic top view of a gate trench silicon carbide power MOSFET according to certain embodiments of the present invention.

FIG. 2B is a schematic top view of the gate trench silicon carbide power MOSFET of FIG. 2A with various of the upper metal and dielectric layers removed.

FIG. 2C is a schematic cross-sectional view of the gate trench silicon carbide power MOSFET of FIGS. 2A-2B that is taken along line 2C-2C of FIG. 2A.

FIGS. 3A-3E are schematic cross-sectional views illustrating a method of fabricating the gate trench silicon carbide power MOSFET of FIGS. 2A-2C.

FIG. 4 is a flow chart illustrating a method of fabricating the gate trench silicon carbide power MOSFET of FIGS. 2A-2C.

FIGS. 5A-5B are schematic cross-sectional views of two modified versions of the gate trench silicon carbide power MOSFET of FIGS. 2A-2C where the cross-sections are taken along line 2C-2C of FIG. 2A.

FIGS. 6A-6B are schematic cross-sectional views of two additional gate trench silicon carbide power MOSFETs according to certain embodiments of the present invention.

### DETAILED DESCRIPTION

Vertical silicon carbide based power semiconductor devices that have gate trenches such as vertical power MOSFETs and IGBTs are attractive for many applications due to their inherent lower specific on-resistance, which may result in more efficient operation for power switching operations. The channels in a gate trench vertical power device are formed in the sidewalls of the gate trenches, and hence are vertical channels. The carrier mobility in these vertically-oriented sidewall channels may be about 2-4 times higher than the corresponding carrier mobility in the horizontal channel of a standard planar (i.e., non-gate trench) vertical power device, which results in increased current density during on-state operation allowing for higher switching speeds. The gate trench design also reduces the overall pitch of the device, which increases device integration. The lower conduction losses (due to the reduced on-state resistance) and improved switching speeds make gate trench power devices particularly well-suited for high frequency power applications having low to moderate voltage blocking requirements (e.g., 600-1200 Volts). These devices may have reduced requirements for associated passive components and require relatively simple cooling schemes.

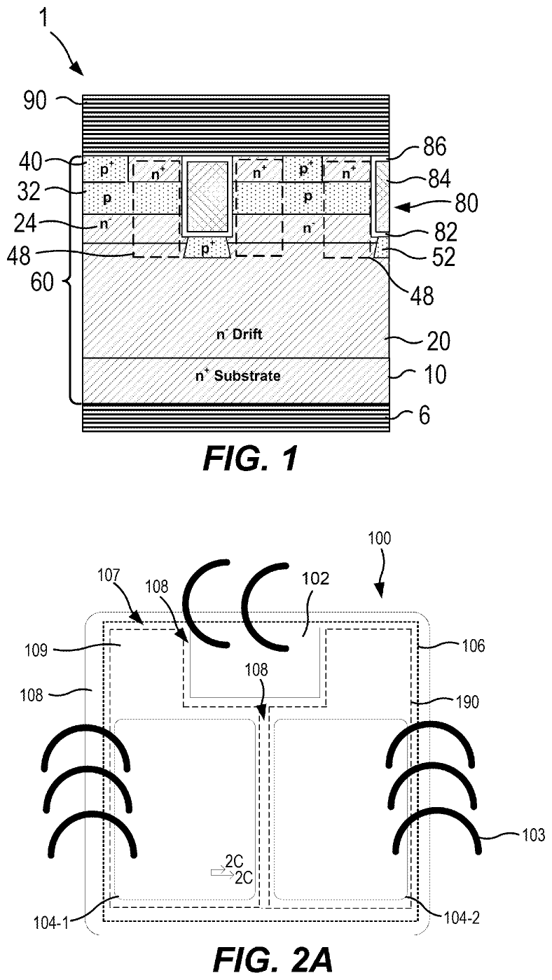

FIG. 1 is a schematic cross-sectional view of a small portion of a silicon carbide power MOSFET 1. The cross-section of FIG. 1 shows one full unit cell of the MOSFET 1 and portions of two adjacent unit cells. As shown in FIG. 1, the MOSFET 1 includes a heavily-doped n-type (n+) silicon carbide semiconductor substrate 10. A lightly-doped n-type (n⁻) silicon carbide drift region 20 is provided on the upper surface of the substrate 10. A plurality of n-type silicon carbide JFET regions 24 are formed on the upper surface of the drift region 20. The JFET regions 24 may be more heavily doped than the drift region 20. Moderately-doped (p) silicon carbide p-type wells 32 (also referred to as “p-wells”) are provided on the n-type JFET regions 24. Each p-well 30 may include a more heavily doped (p+), upwardly-extending well contact region 38. Heavily-doped (n+) n-type silicon carbide source regions 40 are formed in upper portions of the p-wells 32. The substrate 10, the drift region 20, the JFET regions 24, the p-wells 32 and source regions 40, along with p-type trench shielding regions 52 (discussed below), form a semiconductor layer structure 60 of the MOSFET 1.

As is further shown in FIG. 1, plurality of gate trenches 80 are formed in the upper surface of the semiconductor layer structure 60. A gate oxide layer 82 is formed conformally within each gate trench 80, and gate electrodes 84 are formed in the gate trenches 80 on the gate oxide layers 82. A p-type trench shielding region 52 is formed underneath each gate trench 80, typically by implanting p-type dopants through the bottoms of the gate trenches 80. The p-type trench shielding regions 52 extend underneath the respective gate trenches 80 for all or substantially all of the length of the gate trench 80 and may be moderately or heavily doped (p⁺) silicon carbide regions. The p-type trench shielding regions 52 act to reduce the electric field levels that form in gate oxide layers 82 during reverse blocking operation. An intermetal dielectric pattern 88 covers the gate electrodes 84. A source metallization layer 90 is formed on the intermetal dielectric pattern 88 and on the heavily-doped n-type source regions 40 and the well contact regions 38. A drain contact 6 is formed on the lower surface of the substrate 10.

As will be discussed in greater detail below, a parasitic bipolar junction transistor 48 is formed in the semiconductor layer structure 60. In particular, the n-type drift/JFET regions 20/24, the p-type well region 32 and the n-type source region 40 of each unit cell form respective n-p-n bipolar junction transistors 48 in the semiconductor layer structure 60. A breakdown voltage of the power MOSFET 1 is determined by this parasitic bipolar junction transistor 48, since if this transistor is turned on then current will flow between the source and drain terminals regardless of the applied gate bias voltage, which may allow current flow during reverse blocking operation. The higher the doping concentration of the region forming the base of the parasitic bipolar junction transistor 48 (i.e., the doping concentration of the p-well 32) the greater recombination that will occur in the base region, which may prevent the parasitic bipolar junction transistor 48 from turning on at high drain bias voltages (i.e., during reverse blocking operation).

In power MOSFET 1, the portion of each p-well 32 that extends next to a gate electrode 84 (and is separated from the gate electrode 84 by the gate dielectric layer 82) is referred to as a channel, because when a gate bias voltage that exceeds the threshold voltage of the MOSFET is applied to the gate electrode 84, a conductive n-type inversion layer is formed in this portion of the p-well 32 that electrically connects the n-type source region 40 to the n-type drift/JFET regions 20/24.

The gate voltage that is necessary to invert the channel portion of each p-well 32 (i.e., the threshold voltage of MOSFET 1) is a function of the p-type doping concentration of the channel portion of the p-well. The carrier mobility in the channel portion of power MOSFET 1 is also a function of the doping concentration of the p-wells 32. The higher the p-type doping concentration, the greater the threshold voltage of the MOSFET, and the lower the channel mobility. The p-wells in conventional gate trench MOSFETs are typically doped to moderate levels (e.g., p-type doping concentrations of 5×10¹⁶ to 1×10¹⁸) in order to ensure good channel mobility and a low threshold voltage. However, because the p-wells only have moderate doping concentrations, the breakdown voltage rating of these MOSFETs may be lower than desired because of the parasitic bipolar junction transistor that is formed in the semiconductor layer structure 160.

Pursuant to embodiments of the present invention, gate trench power MOSFETs (and other gate trench power semiconductor devices) are provided that have well regions that include both a channel region and a deep well region. In these MOSFETs, the channel region (which is the portion of each well region adjacent the gate electrode) may have a doping concentration that is optimized for the threshold voltage and channel mobility performance of the device. The deep well region of each well region may be formed below a respective one of the source regions and laterally adjacent its associated channel region. The deep well regions may each have a higher doping concentration than their associated channel regions, where the doping concentration of the deep well regions is optimized for the breakdown performance of the device. As a result, the power semiconductor devices according to embodiments of the present invention may exhibit improved performance as compared to conventional devices such as the MOSFET 1 of FIG. 1.

In some embodiments, the channel region of each well region may be located underneath a highly-doped source region of the MOSFET. In such embodiments, the channel regions may be vertical channel regions that extend in sidewalls of the gate trenches. These embodiments may have relatively short channel lengths, which may improve performance, and may have relatively low on-state resistances since the current flows from the source metallization through highly doped source regions to the channel regions. In other embodiments, the channel region of each well region may be located underneath a moderately-doped portion of the source region of the MOSFET. In these embodiments, each source region may include a moderately-doped portion that is adjacent the gate trench and a highly-doped portion that is spaced apart from the gate trench. These embodiments may again have relatively short channel lengths, and may exhibit increased short circuit times, which is advantageous, but may have a higher on resistance due to the lower doping of part of each source region. Each of the above-described MOSFETs having channel regions that are located underneath the respective source regions may have gate electrodes that are recessed within the gate trenches. These MOSFETs may also include support shields that are provided in between adjacent gate trenches to provide increased protection to the gate oxide layers during reverse blocking operation.

In other embodiments, the channel region of each well region may extend to the upper surface of the semiconductor layer structure of the device. In these embodiments, T-shaped gate electrodes (in cross-section) may be provided in the respective gate trenches, where each gate electrode has a lower, vertical section that extends adjacent the sidewall of first and second channel regions of respective first and second p-wells, and an upper, horizontal section that extends over/above the upper portions of the first and second channel regions. A first side of the first channel region may be adjacent a gate trench and a second, opposed side of the first channel region may be adjacent both a first source region and a first deep well region, where the first deep well region is positioned underneath the first source region. The upper, horizontal section of the T-gate electrode may also extend onto the first source region. When a gate bias voltage that exceeds the threshold voltage is applied to the gate electrode, a horizontally-oriented channel is formed in the upper portion of the first channel region underneath the upper, horizontal section of the gate electrode and a vertically-oriented channel is formed in the side of the channel region that is adjacent the lower, vertical section of the gate electrode.

The power semiconductor devices according to some embodiments of the present invention may have channel regions that horizontally overlap both a gate trench and a source region of the device. As used herein, two elements of a semiconductor device are considered to “horizontally overlap” if an axis that is parallel to the major surfaces of a semiconductor layer structure of the semiconductor device intersects both elements. References will also be made herein to elements that “vertically overlap.” As used herein, two elements of a semiconductor device are considered to “vertically overlap” if an axis that is perpendicular to the major surfaces of a semiconductor layer structure of the semiconductor device intersects both elements. The power semiconductor devices according to some embodiments of the present invention may have channel regions that each have both a horizontal segment and a vertical segment, where the vertical segment is deeper in the semiconductor layer structure than the horizontal segment.

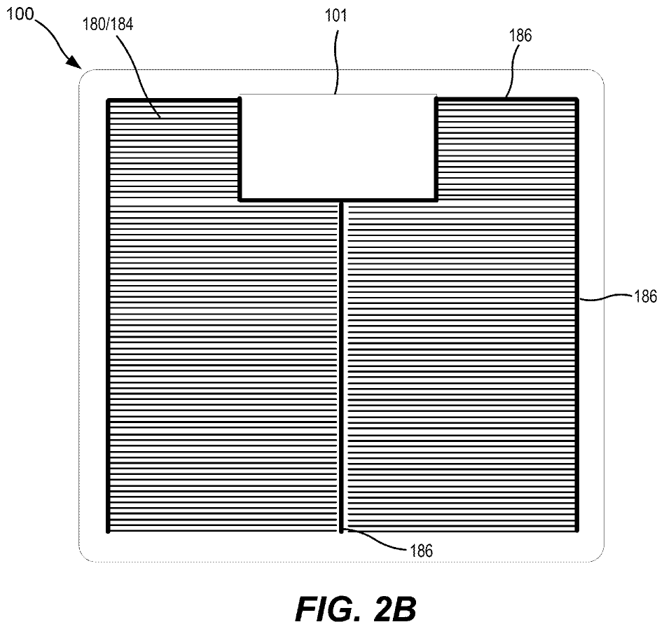

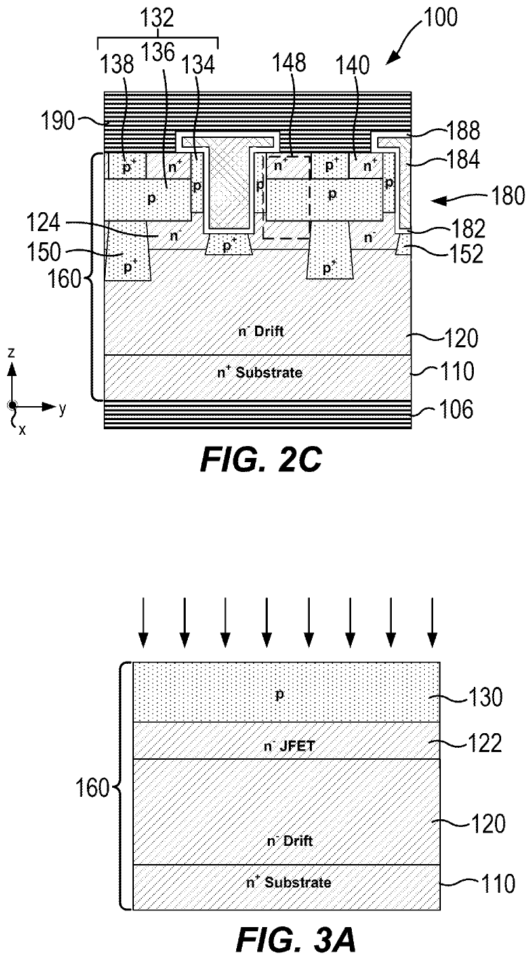

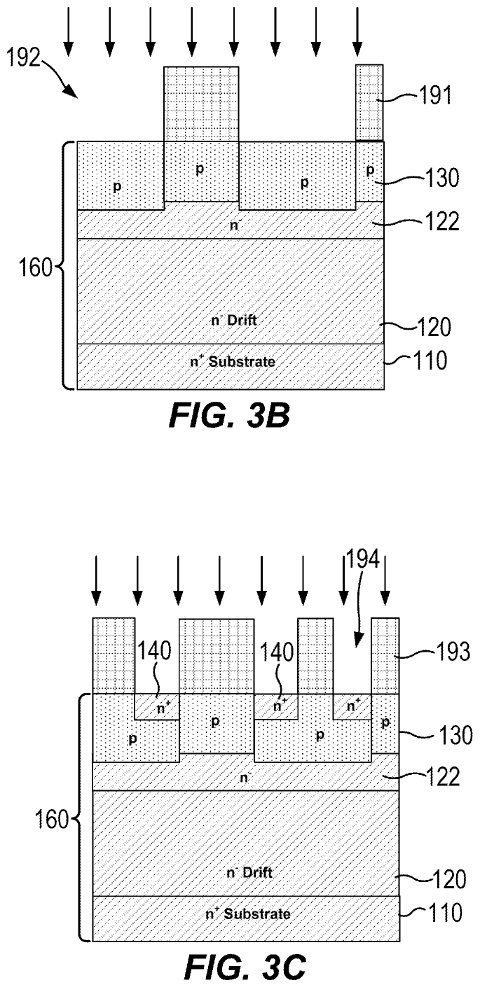

Embodiments of the present invention will now be described in more detail with reference to FIGS. 2A-6B. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations.

As MOSFETs are the most widely used silicon carbide based gate trench power semiconductor devices, the discussion below focuses on MOSFET embodiments. It will be appreciated, however, that the same techniques may be used to form other gate trench power semiconductor devices such as IGBTs, gate-controlled thyristors and the like. It will also be appreciated that each of the described embodiments may alternatively be implemented using non-oxide gate dielectric layers (e.g., nitrides, high dielectric constant materials, etc.),

FIG. 2A is a schematic top view of a gate trench silicon carbide power MOSFET 100 according to certain embodiments of the present invention. FIG. 2B is a schematic plan view of the power MOSFET 100 with various top-side metal and dielectric layers thereof omitted to show the gate electrodes and gate buses. FIG. 2C is a schematic cross-sectional view of a few unit cells of the gate trench silicon carbide power MOSFET 100 that is taken along line 2C-2C of FIG. 2A. It will be appreciated that the thicknesses of various of the layers and regions in FIGS. 2A-2C are not necessarily drawn to scale. The same is true with respect to the other figures included in this application.

The power MOSFET 100 includes a semiconductor layer structure 160 (see FIG. 2C) that comprises one or more semiconductor substrates and/or layers. At least one of the semiconductor layers in the semiconductor layer structure 160 may be a silicon carbide layer. Various metal and/or dielectric layers are formed on either side of the semiconductor layer structure 160 and/or embedded in the semiconductor layer structure 160.

As shown in FIG. 2A, the top-side metal layers include a gate bond pad 102 and one or more source bond pads 104-1, 104-2 that are formed on the upper side of the semiconductor layer structure 160. A metal drain pad 106 (shown as a dotted box in FIG. 2A) is provided on the bottom side of the power MOSFET 100. The gate bond pad 102, the source bond pads 104 and the drain pad 106 form the respective gate, source and drain terminals of power MOSFET 100. The gate and source pads 102, 104 may each be formed of a metal, such as aluminum, that bond wires can be readily attached to via conventional techniques such as thermo-compression or soldering. The drain pad 106 may likewise be a metal pad. A protective layer 109 such as a polyimide layer may cover the entire upper surface of power MOSFET 100 except for the gate and source pads 102, 104.

The power MOSFET 100 further includes a source metallization layer 190 (indicated by the dashed boxes in FIG. 2A) that electrically connects certain regions of the semiconductor layer structure 160 to the source bond pads 104-1, 104-2. The source bond pads 104-1, 104-2 may be portions of the source metallization layer 190 that are exposed through openings in the protective layer 109 or may be separate metal layers. The source metallization layer 190 may generally overlie or correspond to an “active region” 107 of the power MOSFET 100 where the unit cell transistors are located. An inactive region 108 of power MOSFET 100 surrounds the active region 107. The inactive region 108 may include a termination region that extends around the periphery of the MOSFET 100 that includes guard rings, junction termination elements or other termination structures (not shown), a gate pad region that underlies the gate pad 102, and gate bus regions (discussed below).

Bond wires 103 are shown in FIG. 2A that may be used to connect the gate bond pad 102 and the source bond pads 104 to external circuits or the like. The drain pad 106 on the bottom side of power MOSFET 100 may be connected to an external circuit through, for example, an underlying submount (not shown).

FIG. 2B is another plan view of power MOSFET 100 with the gate and source bond pads 102, 104, the polymide layer 109, the source metallization layer 190, the intermetal dielectric layers 188 and various other metal and dielectric layers removed to show the gate electrodes 184 that are formed in the gate trenches 180 in the semiconductor layer structure 160. A patterned field oxide layer (not shown) is formed on the semiconductor layer structure 160 in the inactive region 108 of the MOSFET 100. The field oxide layer may be a relatively thick oxide layer (e.g., ten to twenty times thicker than the gate oxide layers that are discussed below). A polysilicon layer 101 may be formed on the field oxide layer and may be formed in the region where the gate bond pad 102 is formed so that the gate bond pad 102 vertically overlaps the field oxide layer and the polysilicon layer 101.

One or more gate buses 186 are provided that extend around the periphery of the active region 107. The field oxide layer typically runs underneath each gate bus 186 as well as underlying the gate bond pad 102. The gate buses 186 are electrically connected to the gate bond pad 102, often through gate resistors (not shown). A plurality of gate trenches 180 (see FIG. 2C) are formed throughout the active region 107. A gate electrode 184 is formed in each gate trench 180. In the depicted MOSFET 100, the gate electrodes 184 extend horizontally across the semiconductor layer structure 160. In other cases, the gate electrodes 184 may extend vertically across the semiconductor layer structure 160, both horizontally-extending and vertically-extending gate electrodes 184 can be provided to form a grid-like gate electrode structure, or annular hexagonal or other-shaped gate electrodes 184 may be used. The gate electrodes 184 may be connected to the gate pad 102 through the gate buses 186. The gate electrodes 184 may comprise, for example, a doped polysilicon pattern. The gate buses 186 may comprise polysilicon and/or metal structures in example embodiments and typically are in the inactive region 108 of power MOSFET 100.

FIG. 2C is a schematic cross-sectional view taken along line 2C-2C of FIG. 2A that illustrates about one and a half unit cells of the power MOSFET 100. As shown in FIG. 2C, the power MOSFET 100 includes an n-type silicon carbide semiconductor substrate 110. The substrate 110 may comprise, for example, a single crystal 4H silicon carbide semiconductor substrate that is heavily-doped with n-type impurities (i.e., an n+ silicon carbide substrate). The impurities may comprise, for example, nitrogen or phosphorous. In example embodiments, the n-type substrate 110 may have a doping concentration of, for example, between 1×10¹⁸ atoms/cm³ and 1×10²¹ atoms/cm³, although other doping concentrations may be used. The substrate 110 may be relatively thick in some embodiments (e.g., 20-100 microns or more). It should be noted that while the substrate 110 is depicted as a relatively thin layer, this is done to allow enlarging the thickness of other layers and regions in FIG. 2C, and it will be appreciated that the substrate 110 will typically be much thicker than shown. The thickness of various other layers of power MOSFET 100 likewise may not be shown to scale in order to allow other portions of the devices to be enlarged in the figures.

A lightly-doped n-type (n−) silicon carbide drift region 120 (which also may be referred to herein as a drift layer 120) is provided on an upper surface of the substrate 110. Typically, the drift region 120 is formed via an epitaxial growth process and is doped during growth. The n-type drift region 120 may have, for example, a doping concentration of 5×10¹⁵ to 5×10¹⁷ dopants/cm³. The n-type drift region 120 may be a thick region, having a vertical height above the substrate 110 of, for example, 3-50 microns, and can be doped during growth.

A plurality of n-type JFET regions 124 may be provided on an upper portion of the n-type drift region 120. The JFET regions 124 are more heavily doped than the n-type drift region 120. The n-type JFET regions 124 may have an n-type dopant concentration of, for example, 5×10¹⁶ to 1×10¹⁸.

The drift region 120 and the substrate 110 together act as a common drain region for the power MOSFET 100. The drain pad 106 is formed on the substrate 110 opposite the drift region 120.

Still referring to FIG. 2C, a plurality of moderately-doped (p) p-type silicon carbide well regions 132 (which are also referred to as p-wells 132) are provided on the upper surfaces of the respective n-type JFET regions 124. The moderately-doped (p) p-type silicon carbide well regions 132 may be formed by epitaxial growth and/or by ion implantation. Each p-well 132 includes a channel region 134, a deep well region 136, and a well contact region 138.

Each channel region 134 may be adjacent a gate trench (discussed below). Each channel region 134 may also extend to an upper surface of the semiconductor layer structure 160. The p-type doping concentration of the channel regions 134 may be selected to, among other things, provide a desired channel mobility and threshold voltage for the MOSFET 100. In example embodiments, the p-type channel regions 134 may have a p-type dopant concentration of between 1×10¹⁶ to 1×10¹⁸.

The deep well regions 136 may extend deeper into the semiconductor layer structure 160 than the channel regions 134. Herein, references to a first element extending deeper into the semiconductor layer structure 160 than a second element indicate that a lower surface of the first element is farther from the upper surface of the semiconductor layer structure 160 than is a lower surface of the second element, where the upper surface of the semiconductor layer structure is the major surface into which the gate trenches are formed. The deep well regions 136 may have a higher doping concentration than the channel regions 134. In some embodiments, a maximum doping concentration of the deep well regions 136 may exceed the maximum doping concentration of the channel regions 134 by at least an order of magnitude (i.e., a factor of ten). In example embodiments, the deep well regions 136 may have a p-type dopant concentration of, for example, between 1×10¹⁷ to 1×10²¹. The doping concentration of the deep well regions 136 may be selected to improve and/or optimize a breakdown voltage of the power MOSFET 100.

The well contact regions 138 may be heavily doped regions having a p-type dopant concentration of, for example, 1×10¹⁸ to 1×10²². The well contact regions 138 may extend upwardly to the upper surface of the semiconductor layer structure 160. A portion of each deep well region 136 that is underneath a respective one of the well contact regions 138 may be converted into a support shield 150 (discussed below).

A heavily-doped (n+) n-type silicon carbide source region 140 is formed on an upper surface of each p-type deep well region 134. The heavily-doped n-type silicon carbide source regions 140 may be formed by ion implantation. The heavily-doped n-type silicon carbide source regions 140 may have a doping concentration of, for example, between 1×10¹⁹ atoms/cm³ and 5×10²¹ atoms/cm³.

A plurality of gate trenches 180 are formed in the upper surface of the semiconductor layer structure 160. P-type trench shielding regions 152 (also called “trench shields” or “bottom shields”) are formed underneath the respective gate trenches 180 and may extend underneath the respective gate trenches 180 for all or substantially all of the length of the gate trench 180. The p-type trench shielding regions 152 may be moderately or heavily doped (p⁺) silicon carbide regions, and may be formed by implanting ions into the bottoms of the gate trenches 180. In example embodiments, each p-type trench shielding region 152 may have a doping concentration between about 1×10¹⁷ and 1×10²¹. In other embodiments, each p-type trench shielding region 152 may have a doping concentration between about 1×10¹⁸ and 1×10²⁰, between about 1×10¹⁹ and 1×10²⁰, between about 1×10¹⁷ and 1×10²⁰, or between about 1×10¹⁸ and 1×10²¹. In example embodiments, each p-type trench shielding region 152 may extend to a depth of between 0.2 and 2.0 microns from bottom surface of its associated gate trench 180. The p-type trench shielding regions 152 may act to reduce the electric field levels that form in gate oxide layers during reverse blocking operation.

While not shown in FIG. 2C, electrical connections are provided, in and/or outside of the active region 107, that electrically connect the p-type trench shielding regions 152 to the p-type silicon carbide well regions 130. U.S. Pat. Nos. 9,887,287 and 11,610,991 each illustrate designs for p-type silicon carbide trench shield connection patterns that can be used to electrically connect p-type trench shielding regions to a p-type silicon carbide well region. Any of the p-type silicon carbide trench shield connection patterns disclosed in these patents (each of which is incorporated herein by reference) can be used to electrically connect the p-type trench shielding regions 152 to the p-type silicon carbide well regions 132. Additionally or alternatively, the p-type trench shielding regions 152 may be directly connected to the source metallization layer 190 through metal or p-type silicon carbide trench shield connection patterns that, for example, are formed in the gate trenches 180, as shown in U.S. Patent Publication No. 2022/0130998, the entire content of which is also incorporated herein by reference.

As is further shown in FIG. 2C, p-type support shields 150 are provided that extend downwardly from the well contact regions 138 into the silicon carbide drift region 120. The p-type support shields 150 may be moderately or heavily doped (p⁺) silicon carbide regions. For example, each p-type support shield 150 may have a doping concentration between about 5×10¹⁶ and 1×10²². In other embodiments, each p-type support shield 150 may have a doping concentration between about 1×10¹⁸ and 1×10²⁰, between about 1×10¹⁹ and 1×10²⁰, between about 1×10¹⁷ and 1×10¹⁹, between about 1×10¹⁷ and 1×10²⁰, or between about 1×10¹⁸ and 1×10²¹. The p-type support shields 150 may have a doping concentration that is graded with depth. In example embodiments, each p-type support shield 150 may extend to a depth of between 0.1 microns and 4.0 microns from the upper surface of the semiconductor layer structure 160. In other embodiments, the depth of each p-type support shield 150 may be between 1.0 and 3.0 microns, between 1.0 and 2.5 microns, between 1.5 and 3.0 microns, between 1.5 and 2.5 microns, or between 0.5 and 2.5 microns. Any of the above dopant concentration ranges for the p-type support shields 150 may be matched with any of the above-listed depths for the p-type support shields 150. The support shields 150 may, for example, extend deeper into the semiconductor layer structure 160 than the trench shielding regions 152 and may be formed by a high-energy ion implantation process. The support shields 150 may extend into the drift region 120 in some embodiments. It will be appreciated that in embodiments in which the support shields 150 extend into the drift region 120 the support shields 150 (which are p-type regions) are not part of the n-type drift region 120 but rather are formed within the drift region 120 and are typically formed by converting selected portions of the drift region 120 into the p-type support shields 150. The support shields 150 may directly connect to the source metallization layer 190 in the active region of the MOSFET 100. The p-type support shields 150 may act to reduce the electric field levels that form in gate oxide layers (discussed below) during device reverse blocking operation, as will be discussed in greater detail below. The p-type support shields 150 may be doped to have a higher p-type dopant concentration, a lower p-type dopant concentration, or approximately the same p-type dopant concentration as the p-type trench shielding regions 152.

The n-type silicon carbide substrate 110, the n-type silicon carbide drift layer 120, the JFET regions 124, the p-type silicon carbide well regions 132 (including the channel regions 134, the deep well regions 136, and the well contact regions 138) the n-type silicon carbide source regions 140, the p-type silicon carbide support shields 150 and the p-type silicon carbide trench shielding regions 152 may together comprise the semiconductor layer structure 160 of the power MOSFET 100.

As noted above, a plurality of gate trenches 180 are formed in the upper portion of the semiconductor layer structure 160. While only one full gate trench 180 and a portion of a second gate trench 180 are shown in the cross-section of FIG. 2C, it will be appreciated from FIG. 2B that the MOSFET 100 may include a large number of gate trenches 180. Each gate trench 180 may extend along a longitudinal axis through the semiconductor layer structure 160, and the gate trenches 180 may extend in parallel to each other as shown best in FIG. 2B. It will be appreciated that the longitudinal axes of the gate trenches 180 extend into the page in the view of FIG. 2C. The gate trenches 180 may be formed via an etching process.

A gate oxide layer 182 is provided in each gate trench 180 to cover the sidewalls and bottom surface of the gate trench 180. Each gate oxide layer 182 also extends onto the upper surface of the semiconductor layer structure 160. Each gate oxide layer 182 may comprise, for example, a silicon oxide (SiO₂) pattern. The gate oxide layers 182 may or may not be connected to each other outside the view of FIG. 2C. The gate oxide layers 182 may be formed generally conformally within the respective gate trenches 180 and on the upper surface of the semiconductor layer structure 160.

A gate electrode 184 is formed on the gate oxide layer 182 in each gate trench 180 and on the upper surface of the semiconductor layer structure 160. Each gate electrode 184 may have a T-shaped cross-section as shown in FIG. 2C. In particular, each gate electrode 184 includes a lower, vertical section 184a that extends between the sidewall of first and second channel regions 134 of respective first and second p-wells 132, and an upper, horizontal section 184b that extends over/above the upper portions of the first and second channel regions 134. The gate electrodes 184 may comprise conductive material such as a silicide (e.g., NiSi, TiSi, WSi, CoSi), doped polycrystalline silicon (poly-Si), and/or a stable conductor. Other suitable materials for the gate electrode 184 include various metals such as Ti, Ta or W or metal nitrides such as TiN, TaN or WN. The gate oxide layers 182 may insulate the gate electrodes 184 from the semiconductor layer structure 160, thereby preventing the gate electrodes 184 from short circuiting to the semiconductor layer structure 160. Each gate electrode 184 may connect to one of the gate buses 186 (see FIG. 2B).

Intermetal dielectric layers 188 are formed that cover each gate electrode 184. A source metallization layer 190 is formed on the upper surface of the semiconductor layer structure 160 and on the intermetal dielectric layers 188. The intermetal dielectric layers 188 insulate the source metallization layer 190 from the gate electrodes 184. Herein, the source metallization layer 190 may also be referred to as the “source contact.” The source metallization layer 190 may comprise a single metal layer or multiple metal layers. Typically multiple metal layers are provided, as the source metallization layer 190 may include a single layer or multi-layer adhesion layer that contacts the semiconductor layer structure 160, one or more barrier layers, and a bulk metal layer (e.g., an aluminum layer).

The power MOSFET 100 may be turned on by applying a gate bias voltage that is above a threshold level to the gate pad 102. The gate bias voltage is transferred to the gate electrodes 184 via the gate buses 186 and creates conductive n-type inversion layers in the channel regions 134 of the well regions 132. In particular, a horizontally-oriented inversion layer is formed in the upper portion of each channel region 134 underneath the upper portion of the respective gate electrodes 184 and a vertically-oriented n-type inversion layer is formed in the side portion of each channel region 134 that is adjacent the lower vertical segment 184a of the respective gate electrodes 184. Thus, each channel region 134 has a horizontal segment and a vertical segment, where the vertical segment is deeper in the semiconductor layer structure 160 than the horizontal segment. During on-state operation, current flows from the source metallization layer 190, through the source regions 140, through the horizontal segments of the channel regions 134, through the vertical segments of the channel regions 134 and then into the JFET regions 124, the drift region 120, the substrate 110 and to the source contact 106.

As discussed above, the channel regions 134 may be doped differently than the deep well regions 136. In particular, the channel regions 134 may have a lower doping concentration than the deep well regions 136. In fact, in some embodiments, a maximum doping concentration of the channel regions 134 may be at least an order of magnitude lower than a maximum doping concentration of the deep well regions 136. As a result, the channel regions 134 may be doped to a level that provides a desired threshold voltage level for the MOSFET and/or a desired channel mobility. This may provide desired device characteristics during on-state operation. Additionally, the deep well regions 136 may be doped to a higher level that suppresses the parasitic bipolar junction transistor 148 that is formed in the semiconductor layer structure 160 of MOSFET from turning on during reverse blocking operation. This may increase the breakdown voltage for power MOSFET 100.

As can be seen from FIG. 2C and the discussion thereof above, pursuant to some embodiments of the present invention semiconductor devices such as MOSFET 100 are provided that comprise a silicon carbide semiconductor layer structure 160 that comprises a drift region 120 having a first (e.g., n) conductivity type, a channel region 134 having a second (e.g., p) conductivity type, and a source region 140 having the first conductivity type. A gate trench 180 extends into an upper surface of the semiconductor layer structure 160. The channel region 134 horizontally overlaps both the gate trench 180 and the source region 140. Alternatively or additionally, the semiconductor device may include a gate electrode 184 having a first portion 184a that is within the gate trench 180 and a second portion 184b that is on an upper surface of the semiconductor layer structure 160, and the channel region 134 may extend to the upper surface of the semiconductor layer structure 160 and the second portion 184b of the gate electrode 184 may vertically overlap the channel region 134.

The semiconductor layer structure 160 may further include a deep well region 136 having the second conductivity type underneath the source region 140, where the deep well region 136 has a maximum doping concentration that exceeds (e.g., by at least an order of magnitude) a maximum doping concentration of a channel portion of the channel region 134. The channel region 134 may also horizontally overlap the deep well region 136. A lower surface of the deep well region 136 may be farther from the upper surface of the semiconductor layer structure 160 than is a lower surface of the channel region 134. A sidewall of the source region 140 may be substantially aligned with a sidewall of the deep well region 136 in some embodiments.

The semiconductor layer structure may also include a JFET region 124 that has the first conductivity type on the upper surface of the drift region 120. The JFET region 124 may have a doping concentration that is higher than a doping concentration of the drift region 120. The deep well region 136 may optionally extend into the JFET region 124. The semiconductor layer structure 160 may also include a support shield 150 having the second conductivity type. The support shield 150 may extend through the JFET region 124 into the drift region 120. In some embodiments, the second portion 184b of the gate electrode 184 may vertically overlap both the channel region 134 and the source region 140. A semiconductor device may further include a gate dielectric layer 182 that has a horizontal segment that extends on an upper surface of the channel region 134 may directly contact both the second portion 184b of the gate electrode 184 and the channel region 134. The channel region 134 may be configured so that during on-state operation current flows parallel to the upper surface of the semiconductor layer structure 160 in a first portion of the channel region 134 and flows perpendicular to the upper surface of the semiconductor layer structure 160 in a second portion of the channel region 134.

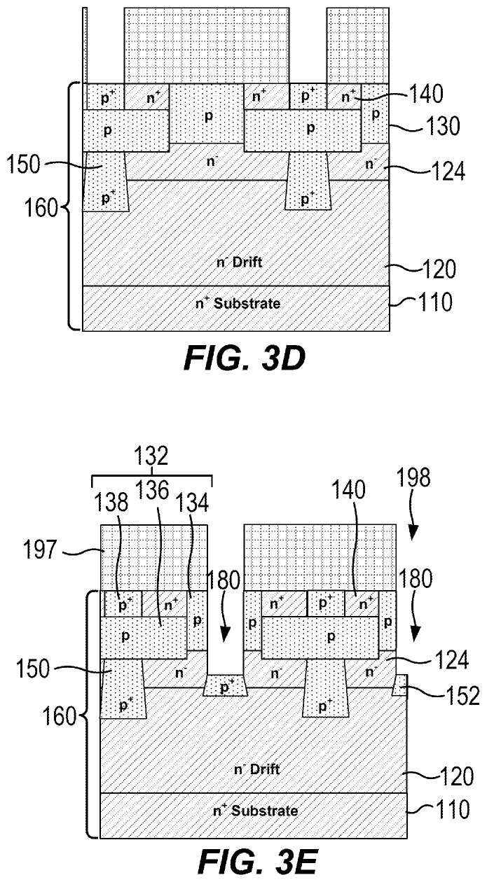

FIGS. 3A-3E are schematic cross-sectional views illustrating a method of fabricating the gate trench silicon carbide power MOSFET 100 of FIGS. 2A-2C.

Referring to FIG. 3A, the n-type silicon carbide substrate 110 is provided. The lightly-doped (n) silicon carbide drift layer 120 is then formed on an upper surface of the substrate 110, typically via epitaxial growth. The n-type dopant concentration may be increased during the growth of the upper portion of the drift layer 120 to form a JFET layer 122 on the drift layer 120. The epitaxial growth process may then continue (with the n-type dopant source left turned on or turned off) to grow an additional semiconductor layer (that will be turned into a p-type well layer 130) on the n-type JFET layer 122. A first ion implantation process is then performed to implant p-type ions into the additional semiconductor layer to convert the additional semiconductor layer into a p-type well layer 130.

Referring to FIG. 3B, a first mask layer such as, for example, an oxide mask layer is formed on the upper surface of the semiconductor layer structure 160. The first mask layer is then patterned to form openings 192 therein to provide a first patterned mask 191 that exposes selected portions of the semiconductor layer structure 160. The openings 192 may be above locations in the semiconductor layer structure 160 in which the deep well regions 136, the well contact regions 138, the source regions 140 and the support shields 150 are formed in subsequent processing steps. A second ion implantation process is then performed to implant additional p-type dopants into the upper portion of the semiconductor layer structure 160 to increase the p-type doping concentration in selected portions of the p-type well layer 130. The p-type dopants may also be implanted more deeply into the semiconductor layer structure 160 in the second ion implantation process than in the first ion implantation process, thereby extending the depth of selected portions of the p-well layer 130. The first patterned mask 191 may then be removed

Referring to FIG. 3C, a second mask layer (e.g., an oxide mask layer) is formed on the upper surface of the semiconductor layer structure 160. The second mask layer is patterned to form openings 194 therein to provide a second patterned mask 193 that exposes selected portions of the semiconductor layer structure 160. The openings 194 may be above locations in the semiconductor layer structure 160 in which the source regions 140 are to be formed. A third ion implantation process is then performed to implant n-type dopants into the exposed portions of the semiconductor layer structure 160. The third ion implantation process may have a heavy dosage so as to convert the upper regions of the exposed portions of the moderately doped p-type well layer 130 into the heavily doped n-type source regions 140. The second patterned mask 193 may then be removed.

Referring to FIG. 3D, a third mask layer (e.g., an oxide mask layer) is formed on the upper surface of the semiconductor layer structure 160. The third mask layer is patterned to form openings 196 therein to provide a third patterned mask 195 that expose selected portions of the semiconductor layer structure 160. The openings 196 may be above locations in the semiconductor layer structure 160 in which the support shields 150 are to be formed. A fourth ion implantation process is then performed to implant p-type dopants into the exposed portions of the semiconductor layer structure 160. The fourth ion implantation process may be a buried ion implantation process in some embodiments so that the support shields 150 are formed underneath the p-well layer 130. It will be appreciated, however, that in other embodiments the fourth ion implantation process may be designed to implant dopants at all depths so that the support shields 150 may extend through the p-type well layer 130. As shown, the support shields 150 may divide the JFET layer 122 into a plurality of JFET regions 124 in some embodiments. The third patterned mask 195 may then be removed.

Referring to FIG. 3E, an etch mask layer is formed on the upper surface of the semiconductor layer structure 160. The etch mask layer is patterned to form openings 198 therein to provide a patterned etch mask 197 that expose selected portions of the semiconductor layer structure 160. The openings 198 may be above locations in the semiconductor layer structure 160 in which the gate trenches 180 are to be formed. An etching process is then performed to etch the gate trenches 180 into the upper surface of the semiconductor layer structure 160. The gate trenches 180 extend all of the way through the p-well layer 130 thereby dividing the p-well layer 130 into a plurality of p-wells 132. Each p-well 132 includes a channel region 134, a deep p-well 136 and a well contact region 138. The patterned etch mask 197 may then be removed.

Referring again to FIG. 2C, the gate oxide layers 182 and gate electrodes 184 may then be formed in the gate trenches 180, and the intermetal dielectric layers 188 are formed to cover the gate oxide layers 182 and gate electrodes 184. The source metallization layer 190 is then formed on the well contact regions 138, the source regions 140 and the intermetal dielectric layers 188. The drain pad 106 is then formed on the bottom of the substrate 110.

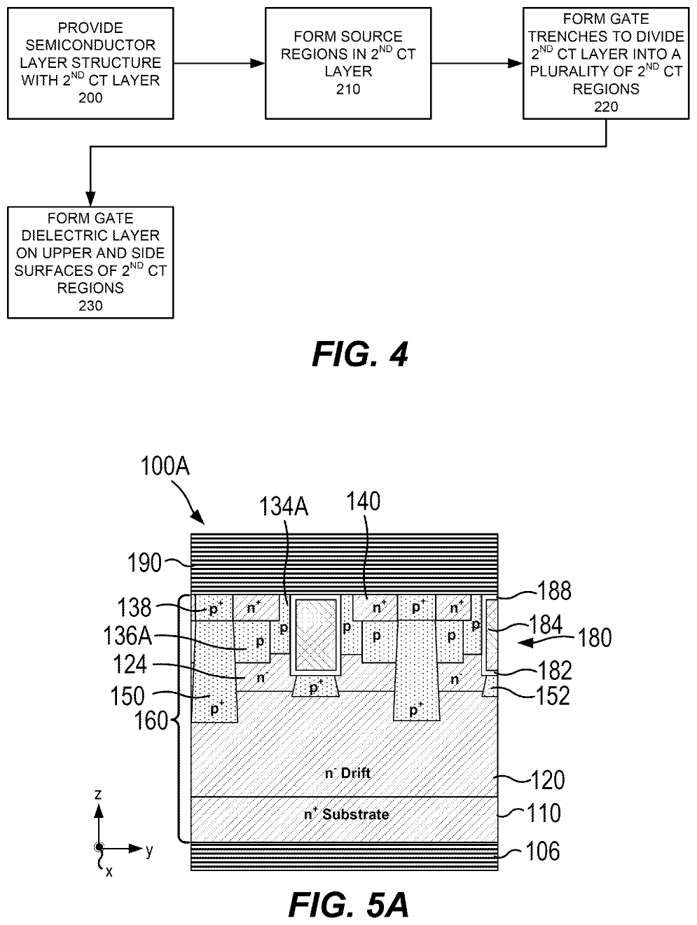

FIG. 4 is a flow chart illustrating a method of forming the gate trench silicon carbide power MOSFET of FIGS. 2A-2C. As shown in FIG. 4, first a silicon carbide based semiconductor layer structure 160 is provided that includes a first conductivity type (“CT”) drift region 120 and a second conductivity type layer 130 on an upper surface of the drift region, the second conductivity type layer extending to an upper surface of the semiconductor layer structure 160 (Block 200). Next, first conductivity type dopants are selectively implanted into the upper surface of the second conductivity type layer to form a plurality of spaced apart first conductivity type source regions 140 in the upper surface of the semiconductor layer structure 160 (Block 210).

A plurality of gate trenches 180 are then etched into the upper surface of the semiconductor layer structure 160, the gate trenches 180 dividing the second conductivity type layer 130 into a plurality of second conductivity type well regions 132 (Block 220). Each second conductivity type well region 132 comprises a channel region 134 that is adjacent a respective one of the gate trenches 180, a deep well region 136 that is underneath a respective one of the source regions 140 and a well contact region 138 that is laterally adjacent the respective one of the source regions 140. Finally, a gate dielectric layer 182 is formed in the gate trench 180 and on the upper surface of the semiconductor layer structure 160, the gate dielectric layer 182 directly contacting both a side surface and an upper surface of a first of the second conductivity type well regions 132.

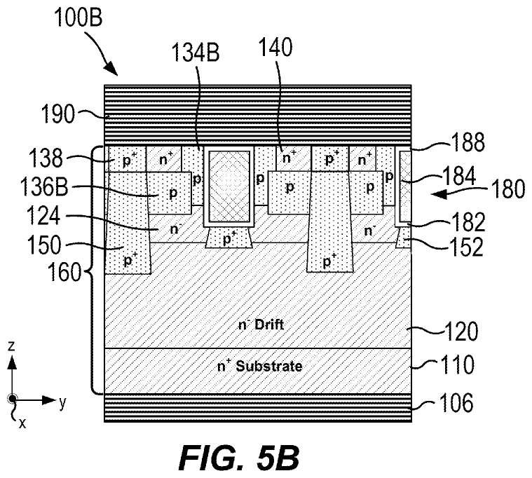

It will be appreciated that the processing steps discussed above with reference to FIGS. 3A-3E and 5 could be performed in different orders in further embodiments. It will also be appreciated that some of the processing steps could be omitted in other embodiments, and/or that other processing steps may be added to the method.

FIGS. 5A-5B are schematic cross-sectional views of gate trench silicon carbide power MOSFETs 100A-100B, respectively, that are modified versions of the gate trench silicon carbide power MOSFET 100. Gate trench silicon carbide power MOSFETs 100A-100B are almost identical to MOSFET 100, so the discussion below will focus solely on the difference between each of MOSFETs 100A-100B and MOSFET 100.

As can be seen by comparing FIG. 2C and FIG. 5A, the only difference between MOSFET 100 and MOSFET 100A is that a lateral width of each deep well region 136A in MOSFET 100A is smaller than the lateral width of each deep well region 136 included in MOSFET 100. As such, the sidewalls of the source regions 140 that are closest to the gate trenches 180 are no longer aligned with the sidewalls of the deep well regions 136A that are closest to the gate trenches 180. A lateral width of the lower portion of each channel region 134A in MOSFET 100A is also expanded so that it is greater than the lateral width of the upper portion of the channel region 134A. Otherwise, MOSFET 100A may be identical to MOSFET 100, so further description thereof will be omitted.

As can be seen by comparing FIG. 2C and FIG. 5B, the only difference between MOSFET 100 and MOSFET 100B is that a lateral width of each deep well region 136B in MOSFET 100B is larger than the lateral width of each deep well region 136 included in MOSFET 100. As such, the sidewalls of the source regions 140 that are closest to the gate trenches 180 are no longer aligned with the sidewalls of the deep well regions 136B that are closest to the gate trenches 180. A lateral width of the lower portion of each channel region 134B in MOSFET 100B is decreased so that it is less than the lateral width of the upper portion of the channel region 134B. Otherwise, MOSFET 100B may be identical to MOSFET 100, so further description thereof will be omitted.

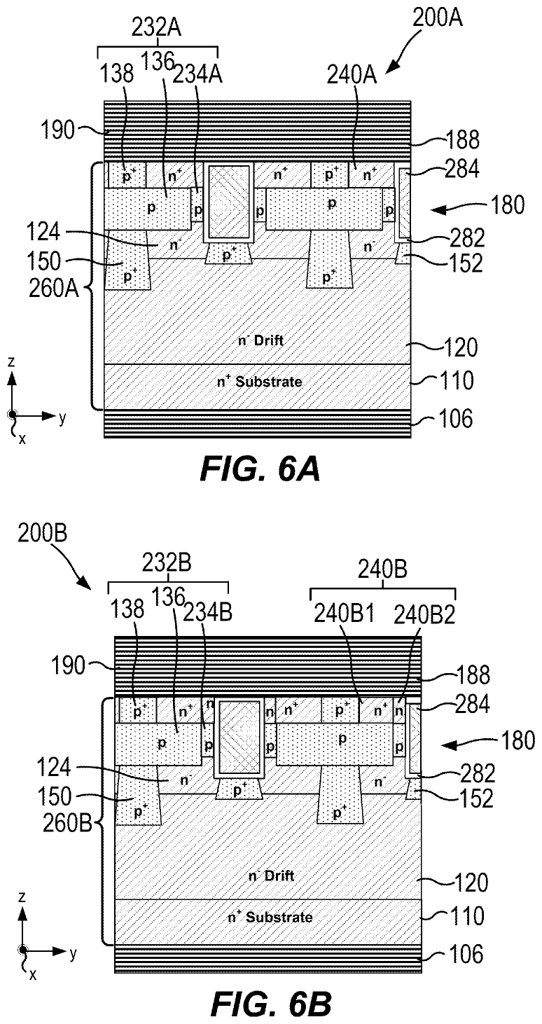

FIGS. 6A-6B are schematic cross-sectional views of gate trench silicon carbide power MOSFETs 200A-200B, respectively, according to further embodiments of the present invention. MOSFETS 200A, 200B may each have the design of FIGS. 2A and 2B, where the cross-sections of FIGS. 6A-6B are taken along line 2C-2C of FIG. 2A. As power MOSFETs 200A-200B are similar to power MOSFET 100 of FIGS. 2A-2C, the discussion below will focus on the differences between power MOSFETs 200A, 200B and power MOSFET 100.

As can be seen by comparing FIG. 2C and FIG. 6A, the primary differences between MOSFET 100 and MOSFET 200A are that (1) power MOSFET 200A includes gate electrodes 284 that are recessed within the gate trenches 180 (or, alternatively may be coplanar with the supper surface of the semiconductor layer structure 260A) while power MOSFET 100 has T-shaped gate electrodes 184, (2) the channel regions 234A in MOSFET 200A are positioned underneath the source regions 240A while the channel regions 134 in MOSFET 100 extend to the upper surface of the semiconductor layer structure 160 and are positioned beside the source regions 140, and (3) the channel regions 234A in MOSFET 200A are shorter than the channel regions 134 in MOSFET 100.

The use of the recessed gate electrodes 284 may be advantageous because the recessed gate electrodes 284 do not extend around the portions of the gate dielectric layers 282 that are formed over the upper corners of the gate trenches 180, as is the case with the T-shaped gate electrodes 184 of power MOSFET 100. During on state-operation of power MOSFET 100, electric fields generated in response to the bias voltage applied to the gate electrodes 184 and the current flowing through the MOSFET 100 may extend into the gate oxide layers 182. Due to electric field crowding effects, the highest electric field values during on-state operation may form in the portions of the gate oxide layers 182 that extend around the upper corners of the gate trenches 180 in power MOSFET 100. In power MOSFET 200A, the gate electrodes 284 are recessed below the upper surfaces of the gate trenches 180 and hence do not apply a strong electric field across the portions of the gate dielectric layers 282 that extend around the upper corners of the gate trenches 180. Consequently, the electric field values are lower in the portions of the gate dielectric layers 282 of power MOSFET 200A that extend around the upper corners of the gate trenches 180 during on-state operation, and thus these portions of the gate dielectric layers 282 are less susceptible to breakdown from on-state operation than is the case with power MOSFET 100.

Positioning the channel regions 234A in power MOSFET 200A underneath, as opposed to beside, the source regions 240A in power MOSFET 200A may advantageously reduce the length of the channel regions 234A, as the channel regions 234A in power MOSFET 200A only have vertically-extending components. The shorter channel regions 234A may, among other things, reduce the on-state resistance of power MOSFET 200A as compared to power MOSFET 100. The provision of the more heavily doped deep well regions 136 may, as discussed above, provide protection to the gate oxide layers 282 during reverse blocking operation and may also suppress the parasitic bipolar junction transistor that is formed in the semiconductor layer structure 260A from turning on during reverse blocking operation, as discussed in detail above. This may advantageously increase the reverse breakdown voltage of power MOSFET 200A as compared to a conventional power MOSFET.

Power MOSFET 200A further includes support shields 150. The support shields 150 may also act to provide protection to the gate oxide layers 282 during reverse blocking operation, and may, in general, be more effective than the deep well regions 136 at protecting the gate oxide layers 282 as the support shields 150 may extend deeper into the semiconductor layer structure 260A than the deep well regions 136. As such, it is counter-intuitive to include both the more heavily doped deep well regions 136 and the support shields 150 in power MOSFET 200A. Applicants realized, however, that the more heavily doped deep well regions 136 provide the additional benefit of suppressing the parasitic bipolar junction transistor in the semiconductor layer structure 160, and that, as such, providing both the more heavily doped deep well regions 136 and the support shields 150 could improve overall performance.

As can be seen by comparing FIG. 6A and FIG. 6B, the only difference between power MOSFET 200A and power MOSFET 200B is that the source regions 240B in power MOSFET 200B are divided into a highly-doped portion 240B1 and a moderately-doped portion 240B2 that is in between the highly-doped portion 240B1 and the gate trench 180. In particular, the highly-doped portion 240B1 may have a doping concentration of, for example, between 1×10¹⁹ atoms/cm³ and 5×10²¹ atoms/cm³, and the moderately-doped portion 240B2 may have a doping concentration of, for example, between 1×10¹⁷ atoms/cm³ and 1×10¹⁹ atoms/cm³. In some embodiments, the doping concentration of the highly-doped portion 240B1 may be at least one order of magnitude or at least two orders of magnitude higher than a doping concentration of the moderately-doped portion 240B2. By reducing the doping concentration of the portion 240B2 of the source region 240B that is directly adjacent the gate trench increase the short circuit time of MOSFET 200B, which is advantageous, but may have a higher on resistance due to the lower doping of part of each source region 240B. The doping concentration of the highly-doped portions 240B1 of the source regions 240B may be at least an order of magnitude greater than the doping concentration of the moderately-doped portions 240B2 of the source regions 240B in some embodiments.

As discussed above, one potential disadvantage of power MOSFET 100 of FIG. 2C is that the channel has both horizontal and vertical components, which can result in an increased channel length. This potential disadvantage may be at least partially mitigated by reducing the depth of the source region 140 as compared to the source region of a conventional gate trench power MOSFET, which is possible because the depth of the source region need not be controlled to ensure that the source region horizontally overlaps overlap the gate electrode since the source region 140 vertically overlaps the gate electrode in the design of power MOSFET 100. Moreover, since the p-type channel regions 134 extend to the upper surface of the semiconductor layer structure 160, they need not extend as deeply into the semiconductor layer structure 160, and thus the channel regions 134, the deep well regions 136, the gate trenches 180, the support shields 150 and the trench shielding regions 152 may all be formed to shallower depths in the semiconductor layer structure. As a result, the overall increase in the channel length in power MOSFET 100 may be relatively small, and shallower implanted regions may be formed using lower energy implants that may cause reduced damage to the semiconductor layer structure 160.

For example, the thickness of the source regions 140 in the depth (z) direction may be as small as 0.1-0.2 microns in some embodiments. The length of the channel regions 134 (which corresponds to the depths of the p-wells 132) may be, for example, between 0.1 and 1.0 microns in example embodiments, and between 0.1 and 0.4 microns in other embodiments. The depths of the deep well regions 126 may be, for example, between 0.2 and 2.0 microns in example embodiments.

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10%.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a flow chart. It will be appreciated that the steps shown in the flow chart need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device, comprising:
a semiconductor layer structure that comprises a drift region having a first conductivity type, a channel region having a second conductivity type, and a source region having the first conductivity type; and
a gate trench extending into an upper surface of the semiconductor layer structure;
wherein the channel region horizontally overlaps the source region.

2. (canceled)

3. The semiconductor device of claim 1, wherein the semiconductor layer structure further comprises a deep well region having the second conductivity type underneath the source region, the deep well region having a maximum doping concentration that exceeds a maximum doping concentration of a channel portion of the channel region.

4. (canceled)

5. The semiconductor device of claim 3, wherein a lower surface of the deep well region is farther from the upper surface of the semiconductor layer structure than is a lower surface of the channel region.

6-9. (canceled)

10. The semiconductor device of claim 3, the semiconductor layer structure further comprising a JFET region having the first conductivity type on the drift region, the JFET region having a doping concentration that is higher than a doping concentration of the drift region, wherein the deep well region extends into the JFET region.

11-12. (canceled)

13. The semiconductor device of claim 1, further comprising a gate electrode having a first portion that is within the gate trench and a second portion that is on the upper surface of the semiconductor layer structure, wherein the second portion of the gate electrode vertically overlaps the channel region and the source region.

14. The semiconductor device of claim 13, further comprising a gate dielectric layer that has a horizontal segment that extends on an upper surface of the channel region and that directly contacts both the second portion of the gate electrode and the channel region.

15. (canceled)

16. The semiconductor device of claim 1, wherein the channel region is configured so that during on-state operation current flows parallel to the upper surface of the semiconductor layer structure in a first portion of the channel region and flows perpendicular to the upper surface of the semiconductor layer structure in a second portion of the channel region.

17. (canceled)

18. A semiconductor device, comprising:
a semiconductor layer structure that comprises a drift region having a first conductivity type, a channel region having a second conductivity type, and a source region having the first conductivity type; and
a gate trench extending into an upper surface of the semiconductor layer structure,
wherein the channel region extends to the upper surface of the semiconductor layer structure.

19. The semiconductor device of claim 18, further comprising a gate electrode having a first portion that is within the gate trench and a second portion that is on an upper surface of the semiconductor layer structure.

20. The semiconductor device of claim 19, wherein the second portion of the gate electrode vertically overlaps the channel region and the source region.

21. The semiconductor device of claim 19, further comprising a gate dielectric layer in between the gate electrode and the semiconductor layer structure, where an upper surface of the channel region directly contacts the gate dielectric layer.

22-28. (canceled)

29. The semiconductor device of claim 19, wherein the channel region is configured so that during on-state operation current flows parallel to the upper surface of the semiconductor layer structure in a first portion of the channel region and flows perpendicular to the upper surface of the semiconductor layer structure in a second portion of the channel region.

30. The semiconductor device of claim 19, wherein a first portion of the channel region that is in between the source region and the gate trench is wider than a second portion of the channel region that is below the first portion of the channel region.

31. The semiconductor device of claim 19, wherein a first portion of the channel region that is in between the source region and the gate trench is narrower than a second portion of the channel region that is below the first portion of the channel region.

32. A semiconductor device, comprising:
a semiconductor layer structure that comprises a drift region having a first conductivity type, a channel region having a second conductivity type, a deep well region having the second conductivity type, a support shield having the second conductivity type, and a source region having the first conductivity type;
a first gate trench extending into the semiconductor layer structure; and
a second gate trench adjacent the first gate trench and extending into the semiconductor layer structure,
wherein the deep well region has a higher second conductivity type dopant concentration than the channel region, and
wherein the support shield is in between the first and second gate trenches and extends deeper into the semiconductor layer structure than the deep well region.

33. The semiconductor device of claim 32, wherein the channel region is below the source region and horizontally overlaps the deep well region.

34. The semiconductor device of claim 32, wherein the channel region extends to the upper surface of the semiconductor layer structure.

35-36. (canceled)

37. The semiconductor device of claim 33, wherein the source region includes a first region having a first dopant concentration and a second region having a second dopant concentration that is less than the first dopant concentration, where the second region is in between the first gate trench and the second region.

38. The semiconductor device of claim 32, the semiconductor layer structure further comprising a JFET region having the first conductivity type on the drift region, the JFET region having a doping concentration that is higher than a doping concentration of the drift region, wherein the deep well region extends into the JFET region.

39. The semiconductor device of claim 38, wherein the support shield extends through the JFET region into the drift region.

40-60. (canceled)
